(19) United States
(12) Patent Application Publication
(10) Pub. No.: US 2019/0371221 A1
(43) Pub. Date: Dec. 5, 2019

(54) DISPLAY DEVICE

(71) Applicant: Panasonic Liquid Crystal Display Co., Ltd., Himeji-shi (JP)

(72) Inventors: Hiroaki GOTO, Osaka (JP); Masafumi HIRATA, Hyogo (JP); Nagatoshi KURAHASHI, Hyogo (JP); Yoshihisa OOISHI, Kanagawa (JP)

(21) Appl. No.: 16/543,204

(22) Filed: Aug. 16, 2019

Related U.S. Application Data
(63) Continuation of application No. PCT/JP2018/003181, filed on Jan. 31, 2018.

(30) Foreign Application Priority Data
Feb. 17, 2017 (JP) 2017-028428

(51) Int. Cl. G09G 3/00; H01L 27/12; G02F 1/1362; G02F 1/1368; G09G 3/36

(52) U.S. Cl. CPC G09G 3/006; H01L 27/124; G02F 2001/136254; G02F 1/1368; G09G 3/3648; G02F 1/136286

(57) ABSTRACT

A display device comprising: source lines; gate lines; selection transistors in each of which a first conduction electrode is electrically connected to each of the gate lines; selection signal supply lines each electrically connected to the control electrode of at least two of the selection transistors; gate voltage supply lines each connected to the second conduction electrode of at least two of the selection transistors; a gate driver electrically connected to the selection signal supply lines and the gate voltage supply lines; failure detection transistors in each of which a control electrode is electrically connected to each of the gate lines; monitor input signal lines each electrically connected the first conduction electrode of at least two of the failure detection transistors; and monitor output signal lines each electrically connected to the second conduction electrode of at least two of the failure detection transistors.

### CROSS-REFERENCE TO RELATED APPLICATION

This application is a bypass continuation of international patent application PCT/JP2018/003181, filed on Jan. 31, 2018 designating the United States of America. Priority is claimed based on Japanese patent application JP 2017-028428, filed on Feb. 17, 2017. The entire disclosures of these international and Japanese patent applications are incorporated herein by reference in their entirety.

### TECHNICAL FIELD

The present invention relates to a display device.

### BACKGROUND ART

In recent years, the number of gate lines has been increased in the display panel with the progress of high definition. With increasing the number of gate lines, the number of lead-out lines of the gate lines also increases to enlarge an area of a frame region. For example, Unexamined Japanese Patent Publication No. 2002-169518 discloses a gate selector system display device as a configuration capable of solving this problem. The gate selector system is a driving system in which the gate lines are divided into a plurality of blocks and scanned in each block. Consequently, the number of lead-out lines of the gate lines can be decreased, so that the area of the frame region can be reduced.

### SUMMARY OF THE INVENTION

### Technical Problem

In the above display device, along with the high definition and the narrow frame, a line width of the gate line or a gate selector signal line is narrowed and a line pitch is narrowed, and a failure is easily generated in these signal lines. For example, disconnection or a short circuit is generated in the gate line, or the disconnection or the short circuit is generated in a signal line controlling on and off of a gate selector thin film transistor (hereinafter, referred to as a selection transistor). The conventional display device does not include means for detecting the failure during display operation. When the failure is generated, a position of the failure is hardly detected even if a display abnormality is generated.

The present invention has been made in view of the above problems, and an object of the present invention is to detect a position of a failure when the failure is generated during the display operation in a gate selector system display device.

### Solution to Problem

According to one aspect of the present invention, a display device includes: a plurality of source lines extending in a first direction; a plurality of gate lines extending in a second direction; a plurality of selection transistors in each of which a first conduction electrode is electrically connected to each of the plurality of gate lines; a plurality of selection signal supply lines each electrically connected to a control electrode of each of the plurality of selection transistors, each of the selection signal supply lines being electrically connected to the control electrode of at least two of the selection transistors; a plurality of gate voltage supply lines each connected to a second conduction electrode of each of the plurality of selection transistors, each of the gate voltage supply lines being electrically connected to the second conduction electrode of at least two of the selection transistors; a gate driver electrically connected to the plurality of selection signal supply lines and the plurality of gate voltage supply lines; a plurality of failure detection transistors in each of which a control electrode is electrically connected to each of the plurality of gate lines; a plurality of monitor input signal lines each electrically connected to a first conduction electrode of each of the plurality of failure detection transistors, each of the monitor input signal lines being electrically connected to the first conduction electrode of at least two of the failure detection transistors; and a plurality of monitor output signal lines each electrically connected to a second conduction electrode of each of the plurality of failure detection transistors, each of the monitor output signal lines being electrically connected to the second conduction electrode of at least two of the failure detection transistors.

In the display device of the present invention, each of the plurality of failure detection transistors electrically connected to one monitor input signal line included in the plurality of monitor input signal lines, among the plurality of failure detection transistors, may be electrically connected to one monitor output signal line included in the plurality of monitor output signal lines.

In the display device of the present invention, the display device may further include a determination part that determines a failure of at least one of the plurality of gate lines, the plurality of gate voltage supply lines, and the plurality of selection signal supply lines based on a voltage level of a monitor output signal output from the plurality of monitor output signal lines.

In the display device of the present invention, the determination part may detect a position of the failure when the failure is generated in at least one of the plurality of gate lines, the plurality of gate voltage supply lines, and the plurality of selection signal supply lines.

In the display device of the present invention, the determination part may determine the failure based on a pattern for one frame of the voltage level of the monitor output signal.

In the display device of the present invention, preferably the number of the plurality of gate voltage supply lines is not an integral multiple of the number of the plurality of monitor output signal lines.

In the display device of the present invention, preferably the least common multiple of the number of the plurality of gate voltage supply lines, the number of the gate lines included in one block, and the number of the plurality of monitor output signal lines is greater than or equal to a total number of the plurality of gate lines.

According to another aspect of the present invention, a display device includes: a plurality of source lines extending in a first direction; a plurality of gate lines extending in a second direction; a plurality of first selection transistors in each of which a first conduction electrode is electrically connected to a first end of each of the plurality of gate lines; a plurality of second selection transistors in each of which a first conduction electrode is electrically connected to a second end of each of the plurality of gate lines; a plurality of first selection signal supply lines each electrically connected to a control electrode of each of the plurality of first selection transistors, each of the first selection signal supply lines being electrically connected to the control electrode of at least two of the first selection transistor; a plurality of second selection signal supply lines each electrically connected to a control electrode of each of the plurality of second selection transistors, each of the second selection signal supply lines being electrically connected to the control electrode of at least two of the second selection transistor; a plurality of first gate voltage supply lines each connected to a second conduction electrode of each of the plurality of first selection transistors, each of the first gate voltage supply lines being electrically connected to the second conduction electrode of at least two of the selection transistors; a plurality of second gate voltage supply lines each connected to a second conduction electrode of each of the plurality of second selection transistors, each of the second gate voltage supply lines being electrically connected to the second conduction electrode of at least two of the selection transistors; a first gate driver electrically connected to the plurality of first selection signal supply lines and the plurality of first gate voltage supply lines; a second gate driver electrically connected to the plurality of second selection signal supply lines and the plurality of second gate voltage supply lines; a plurality of first failure detection transistors in each of which a control electrode is electrically connected to the second end of each of the plurality of gate lines; a plurality of second failure detection transistors in each of which a control electrode is electrically connected to the first end of each of the plurality of gate lines; a plurality of first monitor input signal lines each electrically connected to a first conduction electrode of each of the plurality of first failure detection transistors, each of the first monitor input signal lines being electrically connected to the first conduction electrode of each of at least two of the first failure detection transistors; a plurality of second monitor input signal lines each electrically connected to a first conduction electrode of each of the plurality of second failure detection transistors, each of the second monitor input signal lines being electrically connected to the first conduction electrode of each of at least two of the second failure detection transistors; a plurality of first monitor output signal lines each electrically connected to a second conduction electrode of each of the plurality of first failure detection transistors, each of the first monitor output signal lines being electrically connected to the second conduction electrode of each of at least two of the first failure detection transistors; and a plurality of second monitor output signal lines each electrically connected to a second conduction electrode of each of the plurality of second failure detection transistors, each of the second monitor output signal lines being electrically connected to the second conduction electrode of each of at least two of the second failure detection transistors.

The display device of the second aspect of the present invention may include: a first mode in which the plurality of gate lines are driven by the plurality of first selection transistors, the plurality of first selection signal supply lines, the plurality of first gate voltage supply lines, and the first gate driver while a failure of at least one of the plurality of gate lines, the plurality of first gate voltage supply lines, and the plurality of first selection signal supply lines is determined based on a voltage level of a first monitor output signal output from the plurality of first monitor output signal lines, and a second mode in which the plurality of gate lines are driven by the plurality of second selection transistors, the plurality of second selection signal supply lines, the plurality of second gate voltage supply lines, and the second gate driver while a failure of at least one of the plurality of gate lines, the plurality of second gate voltage supply lines, and the plurality of second selection signal supply lines is determined based on a voltage level of a second monitor output signal output from the plurality of second monitor output signal lines.

In the display device of the second aspect of the present invention, the first mode and the second mode may be switched in a predetermined period.

In the display device of the second aspect of the present invention, when the failure is generated in at least one of the plurality of first gate voltage supply lines and the plurality of first selection signal supply lines in the first mode, subsequent operation may be performed in the second mode, and when the failure is generated in at least one of the plurality of second gate voltage supply lines and the plurality of second selection signal supply lines in the second mode, subsequent operation may be performed in the first mode.

The display device according to the present disclosure can detect a position of a failure when the failure is generated during the display operation in a gate selector system display device.

### BRIEF DESCRIPTION OF DRAWINGS

FIG. 1 is a plan view and a side view illustrating a schematic configuration of a liquid crystal display device according to the present exemplary embodiment.

FIG. 2 is a plan view illustrating a schematic configuration of display panel according to the present exemplary embodiment.

FIG. 3 is a plan view illustrating the detailed configuration of display panel according to the present exemplary embodiment.

FIG. 4 is a timing chart illustrating the operation of the display panel in the general gate selector system.

FIG. 5 is a plan view illustrating a configuration of liquid crystal display device according to Example 1.

FIG. 6 is a timing chart during the normal operation in liquid crystal display device of Example 1.

FIG. 7 is a timing chart in case that disconnection failure on gate line GL8 is generated in liquid crystal display device of Example 1.

FIG. 8 is a timing chart in case that disconnection failure on gate voltage supply line VG3 is generated in liquid crystal display device of Example 1.

FIG. 9 is a timing chart in case that disconnection failure on selection signal supply line CLK3 is generated in liquid crystal display device of Example 1.

FIG. 10 is a timing chart in case that short circuit failure on selection signal supply line CLK6 is generated in liquid crystal display device of Example 1.

FIG. 11 is a plan view illustrating a configuration of liquid crystal display device according to Example 2.

FIG. 12 is a timing chart during the normal operation in liquid crystal display device of Example 2.

FIG. 13 is a timing chart in case that short circuit failure on selection signal supply line CLK6 is generated in liquid crystal display device of Example 2.

FIG. 14 is a timing chart in case that short circuit failure on selection signal supply line CLK12 is generated in liquid crystal display device of Example 2.

FIG. 15 is a plan view illustrating a configuration of liquid crystal display device according to Example 3.

FIG. 16 is a timing chart during the normal operation in liquid crystal display device of Example 3.

FIG. 17 is a timing chart when the selection signal supply line CLK6 is short-circuited in liquid crystal display device of Example 3.

FIG. 18 is a timing chart when the selection signal supply line CLK12 is short-circuited in liquid crystal display device of Example 3.

FIG. 19 is a table illustrating a configuration example of liquid crystal display device according to Example 3.

FIG. 20 is a plan view illustrating a configuration of liquid crystal display device according to a modification example.

### DESCRIPTION OF EMBODIMENT

An exemplary embodiment of the present invention will be described below with reference to the drawings. In the exemplary embodiment of the present invention, a liquid crystal display device is cited as an example of the display device. However, the present invention is not limited to the liquid crystal display device. For example, an organic EL display device may be used as the display device. In the exemplary embodiment of the present invention, a Chip On Glass (COG) system liquid crystal display device is cited as an example. However, the present invention is not limited to the COG system liquid crystal display device. For example, a Chip On Film (COF) system or Tape Carrier Package (TCP) system liquid crystal display device may be used as the display device.

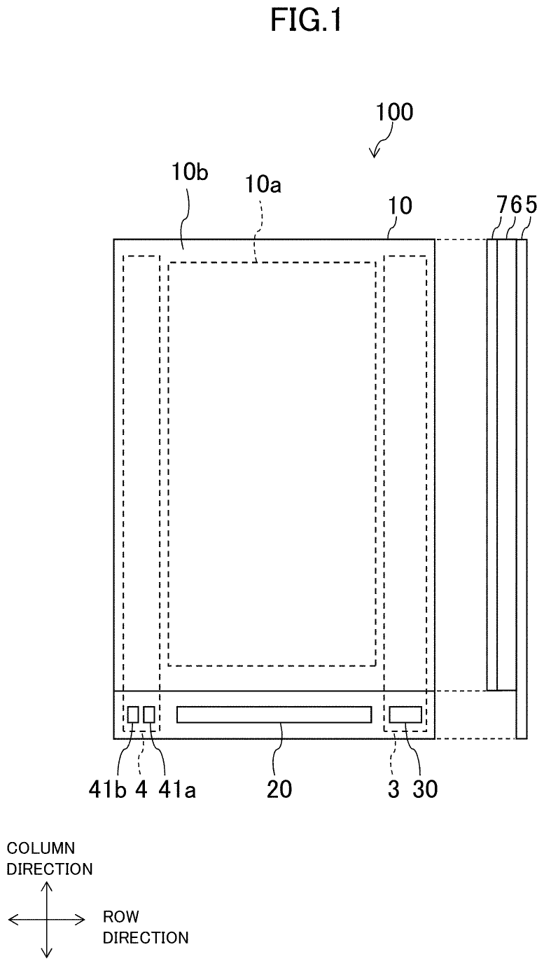

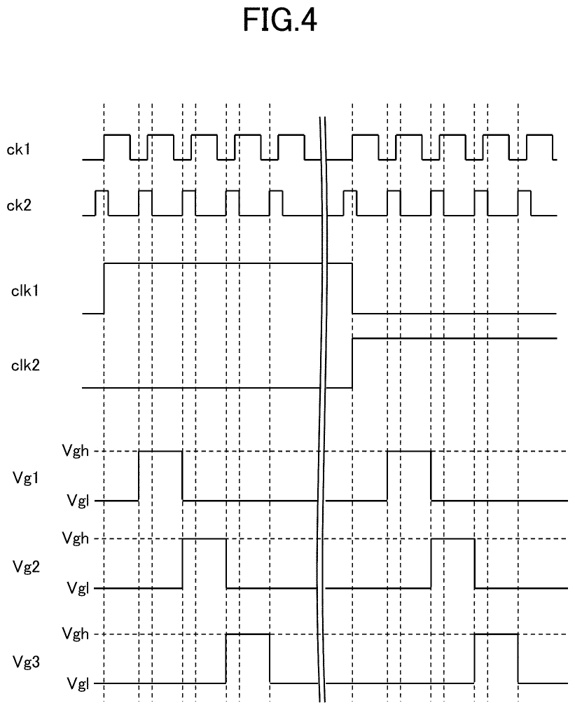

FIG. 1 is a plan view and a side view illustrating a schematic configuration of a liquid crystal display device according to the present exemplary embodiment. Liquid crystal display device 100 includes display panel 10, source driver IC 20, gate driver IC 30, and a backlight device (not illustrated). Display panel 10 includes thin film transistor substrate 5 (TFT substrate), color filter substrate 7 (CF substrate), and liquid crystal layer 6 sandwiched between TFT substrate 5 and CF substrate 7. Source driver IC 20 and gate driver IC 30 are directly mounted on a glass substrate constituting TFT substrate 5. Source driver IC 20 and gate driver IC 30 are disposed in line along one side of display panel 10. Numbers of source drivers IC 20 and gate driver IC 30 are not particularly limited. Display panel 10 includes display region 10a where an image is displayed and frame region 10b around display region 10a. In frame region 10b, gate selector 3 including a circuit and a signal line to implement the gate selector system is disposed on one side (in FIG. 4, the right side) of display region 10a, and failure detector 4 including a circuit and a signal line in order to detect a failure of the gate line or the like is disposed on the other side (in FIG. 4, the left side) of display region 10a. In FIG. 1, reference mark 41a denotes an input part of an input signal (monitor input signal) detecting the failure, and reference mark 41b denotes an output part of an output signal (monitor output signal) detecting the failure. Specific configurations of gate selector 3 and failure detector 4 will be described later.

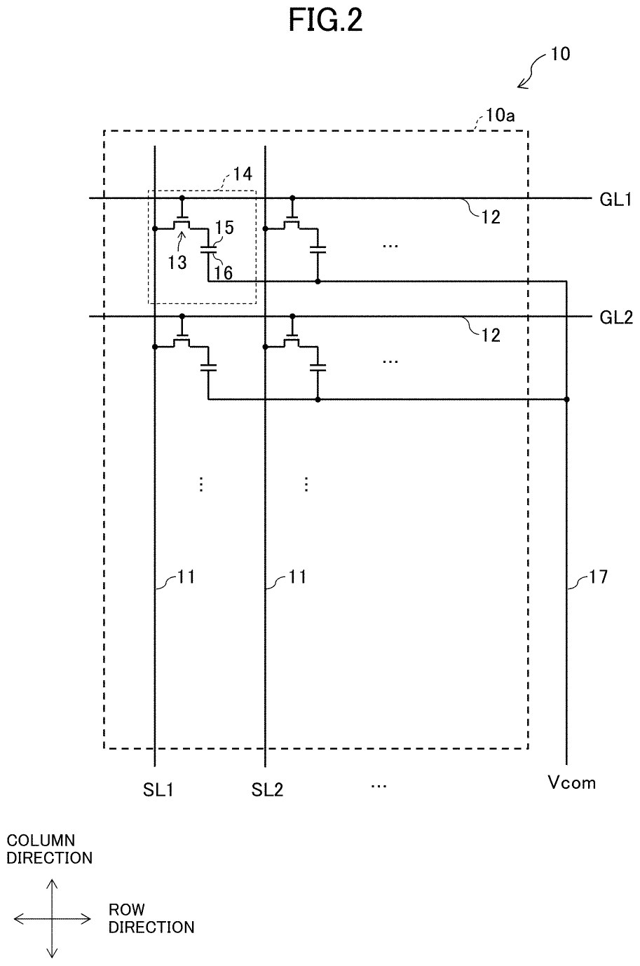

FIG. 2 is a plan view illustrating a schematic configuration of display region 10a of display panel 10. A plurality of source lines 11 extending in a first direction (for example, a column direction) and a plurality of gate lines 12 extending in a second direction (for example, a row direction) are provided in display panel 10. Thin film transistor 13 (hereinafter, referred to as a pixel transistor) is provided at an intersection of each source line 11 and each gate line 12. Each source line 11 is electrically connected to source driver IC 20, and each gate line 12 is electrically connected to gate driver IC 30. Reference mark SL1 denotes first source line 11 disposed at an end in the row direction, and reference mark SL2 denotes second source line 11 adjacent to first source line 11 in the row direction. Reference mark GL1 denotes gate line 12 that is disposed at an end in the column direction and scanned first, and reference mark GL2 indicates gate line 12 scanned second.

In display panel 10, a plurality of pixels 14 are arranged into a matrix shape (the row direction and the column direction) corresponding to the intersections of source lines 11 and gate lines 12. A plurality of pixel electrodes 15 disposed in each pixel 14 and common electrode 16 common to a plurality of pixels 14 are provided in TFT substrate 5. Common electrode 16 may be provided in CF substrate 7.

A data signal (data voltage) is supplied from source driver IC 20 to each source line 11. A gate signal (gate-on voltage, gate-off voltage) is supplied from gate driver IC 30 to each gate line 12. Common voltage Vcom is supplied from a common driver (not illustrated) to common electrode 16 through common line 17. When an on-voltage (gate-on voltage) of the gate signal is supplied to gate line 12, pixel transistor 13 connected to gate line 12 is turned on, and the data voltage is supplied to pixel electrode 15 through source line 11 connected to pixel transistor 13. An electric field is generated by a difference between the data voltage supplied to pixel electrode 15 and common voltage Vcom supplied to common electrode 16. Liquid crystal is driven by the electric field to control transmittance of light emitted from the backlight, thereby displaying an image. In performing color display, a desired data voltage is supplied to source line 11 connected to pixel electrode 15 of pixel 14 corresponding to each of red, green, and blue, which are formed by a stripe-shaped color filter.

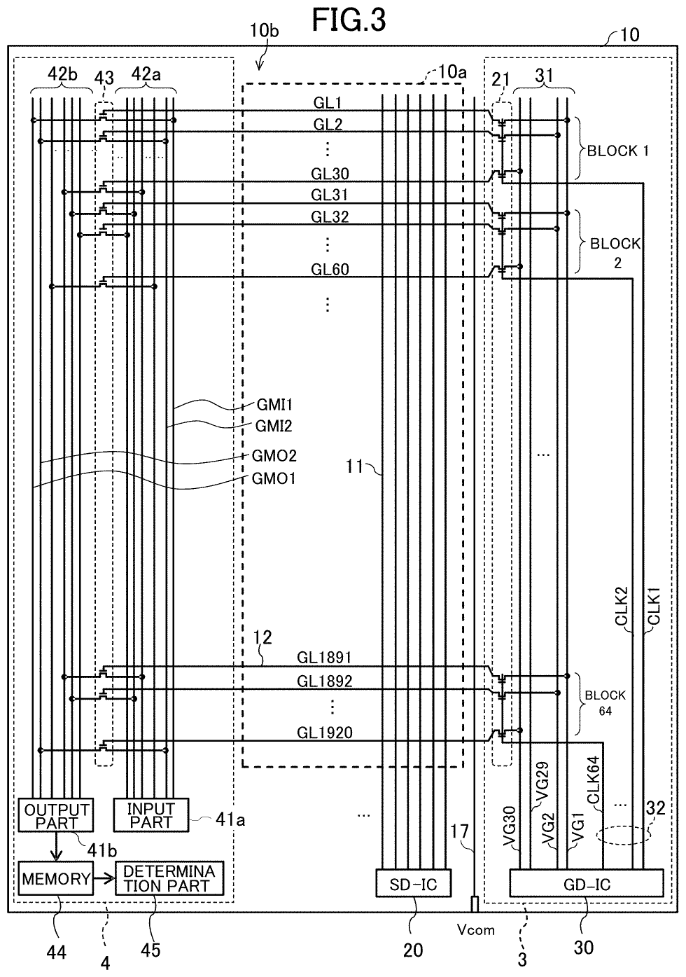

FIG. 3 is a plan view illustrating the detailed configuration of display panel 10. Source driver IC 20 (SD-IC) to which one end of each source line 11 is electrically connected, gate driver IC 30 (GD-IC) to which one end of each gate line 12 is electrically connected, and terminal Vcom to which one end of common line 17 is connected are disposed in frame region 10b of display panel 10. One end (in FIG. 3, the right end) of gate line 12 is connected to gate selector 3. The gate selector 3 includes thin film transistor 21 (hereinafter, referred to as a selection transistor) that selects gate line 12, gate voltage supply line 31 that supplies the gate voltage to gate line 12, and selection signal supply line 32 that supplies a control signal controlling on and off of selection transistor 21. Gate line 12 is connected to one of the conduction electrodes (source electrode) of selection transistor 21, and gate voltage supply line 31 is electrically connected to the other conduction electrode (drain electrode) of selection transistor 21. Selection transistor 21 acts as a switch that selects corresponding gate line 12. The plurality of gate lines 12 are electrically connected to one gate voltage supply line 31. Specifically, for example, when the total number of gate lines 12 is 1920, first, 31st, 61st, . . . , 1891st gate lines GL1, GL31, GL61, . . . , GL1891 are connected to gate voltage supply line VG1 through corresponding selection transistors 21, and the second, 32nd, 62nd, . . . , 1892nd gate lines GL2, GL32, GL62, . . . , GL1892 are connected to gate voltage supply line VG2 through corresponding selection transistors 21. Similarly, 30th, 60th, 90th, . . . , 1920th gate lines GL30, GL60, GL90, . . . , GL1920 are connected to gate voltage supply line VG30 through corresponding selection transistors 21. That is, in the example of FIG. 3, gate lines 12 are electrically connected to identical gate voltage supply line 31 every 30 gate lines 12. Thus, 64 gate lines 12 are electrically connected to one gate voltage supply line 31. 30 adjacent gate lines 12 connected to gate voltage supply lines VG1 to VG30 constitute one block. For example, gate lines GL1 to GL30 constitute one block (block 1), gate lines GL31 to GL60 constitute one block (block 2), and gate lines GL1891 to GL1920 constitute one block (block 64). In the example of FIG. 3, gate lines 12 are divided into 64 blocks.

Each control electrode (gate electrode) of 30 selection transistors 21 corresponding to one block is connected to identical selection signal supply lines 32. For example, in group 1 including gate lines GL1 to GL30, the control electrode of each of 30 selection transistors 21 connected to gate lines GL1 to GL30 is connected to selection signal supply line CLK1. In group 2 including gate lines GL31 to GL60, the control electrode of each of 30 selection transistors 21 connected to gate lines GL31 to GL60 is connected to selection signal supply line CLK2. Similarly, in group 64 including gate lines GL1891 to GL1920, the control electrode of each of 30 selection transistors 21 connected to gate lines GL1891 to GL1920 is connected to selection signal supply line CLK64. That is, different selection signal supply line 32 is provided with respect to each group. Although the number of gate lines 12 per block and the number of gate voltage supply lines 31 are equal to each other in FIG. 3 for the sake of easy understanding, these numbers are set so as to satisfy a predetermined condition. The details of the display device of the present invention will be described later.

The operation of the display panel in the general gate selector system will be described. FIG. 4 is a timing chart illustrating the operation of the display panel in the general gate selector system. The operation of the display panel (see FIG. 3) in the case that gate driver IC 30 supplies gate-on voltage Vgh and gate-off voltage Vgl to the gate voltage supply lines VG1 to VG30 will be described. Reference marks ck1, ck2 in FIG. 4 denote clocks input from a control circuit (not illustrated) to gate driver IC 30, reference marks clk1, clk2 denote voltages (control voltages) supplied to selection signal supply lines CLK1, CLK2, and reference marks Vg1 to Vg3 denote voltages (voltages at gate lines GL1 to GL3) supplied to gate voltage supply lines VG1 to VG3.

Gate driver IC 30 supplies the voltage (gate-on voltage) turning on selection transistor 21 to selection signal supply line CLK1 at rising timing of clock ck1. Consequently, selection transistors 21 connected to gate lines GL1 to GL30 of block 1 are put into an on state. Subsequently, gate driver IC 30 supplies the voltage (gate-on voltage Vgh) turning on pixel transistor 13 (see FIG. 2) to gate voltage supply line VG1 at rising timing of clock ck2. Consequently, first-column pixel transistors 13 connected to gate line GL1 are put into the on state, and the data voltage output from source driver IC 20 is supplied to first-column pixel electrodes 15 through source lines 11 connected to pixel transistors 13. Subsequently, at the rising timing of clock ck2, gate driver IC 30 supplies the gate-on voltage Vgh to gate voltage supply line VG2 while supplying the voltage (gate-off voltage Vgl) turning off pixel transistor 13 to gate voltage supply line VG1. Consequently, first-column pixel transistors 13 connected to gate line GL1 are turned off, second-column pixel transistors 13 connected to gate line GL2 are put into the on state, and the data voltage output from source driver IC 20 is supplied to second-column pixel electrodes 15 through source lines 11 connected to thin film transistors 13. Thus, in display panel 10, gate lines GL1 to GL30 of block 1 are sequentially driven to supply the data voltage to corresponding pixel electrodes 15.

Subsequently, at the rising timing of clock ck1, gate driver IC 30 supplies the gate-on voltage to selection signal supply line CLK2 while supplying the voltage (gate-off voltage) turning off selection transistor 21 to selection signal supply line CLK1. Consequently, selection transistors 21 connected to gate lines GL1 to GL30 of group 1 are turned off, and selection transistors 21 connected to gate lines GL31 to GL60 of group 2 are put into the on state. Subsequently, gate driver IC 30 supplies gate-on voltage Vgh to gate voltage supply line VG1 at the rising timing of clock ck2. Consequently, 31st-column pixel transistors 13 connected to gate line GL31 are put into the on state, and the data voltage output from source driver IC 20 is supplied to 31st-column pixel electrodes 15 through source lines 11 connected to pixel transistors 13. Subsequently, at the rising timing of clock ck2, gate driver IC 30 supplies the gate-on voltage Vgh to gate voltage supply line VG2 while supplying gate-off voltage Vgl to gate voltage supply line VG1. Consequently, 31st-column pixel transistors 13 connected to gate line GL31 are turned off, 32nd-column pixel transistors 13 connected to gate line GL32 are put into the on state, and the data voltage output from source driver IC 20 is supplied to 32nd-column pixel electrodes 15 through source lines 11 connected to pixel transistors 13. As described above, in display panel 10, gate lines GL31 to GL60 of block 2 are sequentially driven to supply the data voltage to corresponding pixel electrodes 15.

After that, in display panel 10, each block is sequentially driven to supply the data voltage to corresponding pixel electrode 15.

In the above configuration, the number of lines connected to gate driver IC 30 is smaller than the number of gate lines 12, so that an area of the frame region in the row direction can be reduced as compared with the configuration in which all gate lines 12 are pulled around the gate driver IC.

Returning to FIG. 3, the specific configuration of failure detector 4 will be described. The other end (in FIG. 3, the left end) of gate line 12 is connected to failure detector 4. The failure detector 4 includes thin film transistor 43 (hereinafter, referred to as a failure detection transistor), in which the control electrode is connected to the other end of gate line 12 and the on and off is controlled by the gate voltage, monitor input signal line 42a electrically connected to one of the conduction electrodes (drain electrode) of failure detection transistor 43, monitor output signal line 42b electrically connected to the other conduction electrode (source electrode) of failure detection transistor 43, input part 41a of an input signal (monitor input signal GMin) detecting the failure, output part 41b of an output signal (monitor output signal GMout) detecting the failure, memory 44 (for example, a frame memory) in which monitor output signal GMout is stored in each one frame, and determination part 45 that determines the failure based on monitor output signal GMout. For example, monitor input signal GMin is input from a timing controller (not illustrated). Memory 44 and determination part 45 may be provided in the timing controller. An output pattern (reference pattern) (to be described later) of monitor output signal GMout output from output part 41b during the normal operation is stored in memory 44.

Failure detection transistor 43 is put into the on state to electrically connect monitor input signal line 42a and monitor output signal line 42b to each other. For example, monitor input signal line GMI1 and monitor output signal line GMO1 are electrically connected to each other when failure detection transistor 43 connected to gate line GL1 is put into the on state, and monitor input signal line GMI2 and monitor output signal line GMO2 are electrically connected to each other when failure detection transistor 43 connected to gate line GL2 is put into the on state. The numbers of monitor input signal lines 42a and monitor output signal lines 42b are decided based on the total number of gate lines 12, the number of gate lines 12 per block, and the number of gate voltage supply lines 31.

In the failure detector 4, for example, when the failure detection transistor 21 connected to gate line GL1 is put into the on state by gate-on voltage Vgh supplied to gate line GL1, monitor output signal GMout corresponding to monitor input signal GMin input to input part 41a is output from output part 41b to memory 44 through monitor output signal line GMO1b. Monitor output signals GMout corresponding to gate lines GL are sequentially input from output part 41b to memory 44, and memory 44 stores the output pattern of monitor output signal GMout for one frame.

Determination part 45 compares the output pattern of the monitor output signal GMout stored in memory 44 to a reference pattern, and detects at least one of gate line 12, gate voltage supply line 31, and selection signal supply line 32.

A specific method for detecting the failure will be described below by giving Examples.

### Example 1

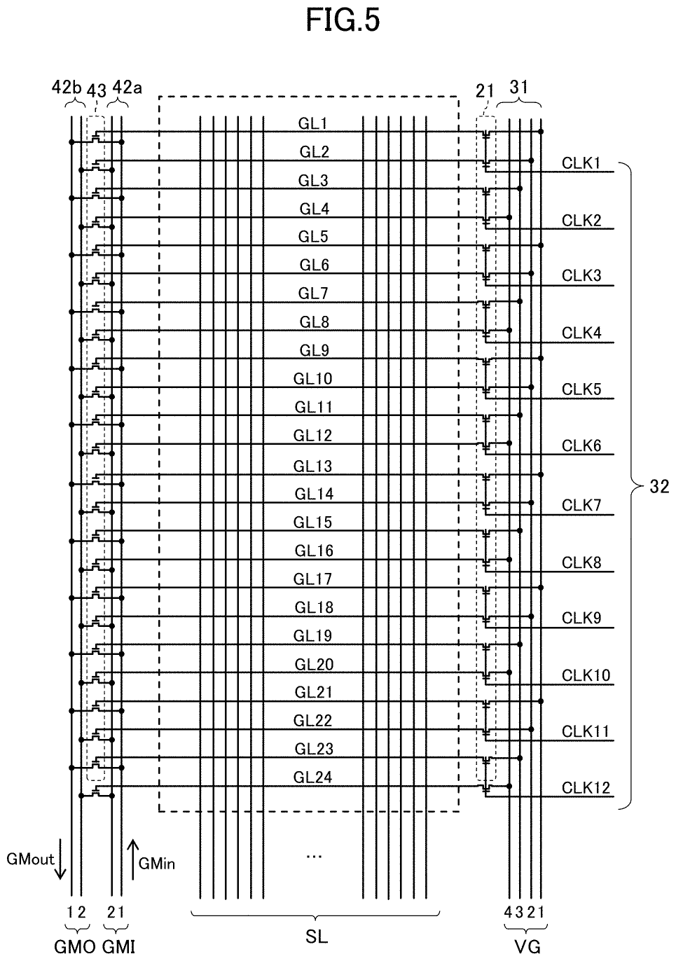

FIG. 5 is a plan view illustrating a configuration of liquid crystal display device 100 according to Example 1. In liquid crystal display device 100 of Example 1, 24 gate lines 12 (GL1 to GL24), 4 gate voltage supply lines 31 (VG1 to VG4), 12 selection signal supply lines 32 (CLK1 to CLK12), two monitor input signal lines 42a (GMI1, GMI2) and two monitor output signal lines 42b (GMO1 and GMO2), and 2 gate lines 12 per block are formed.

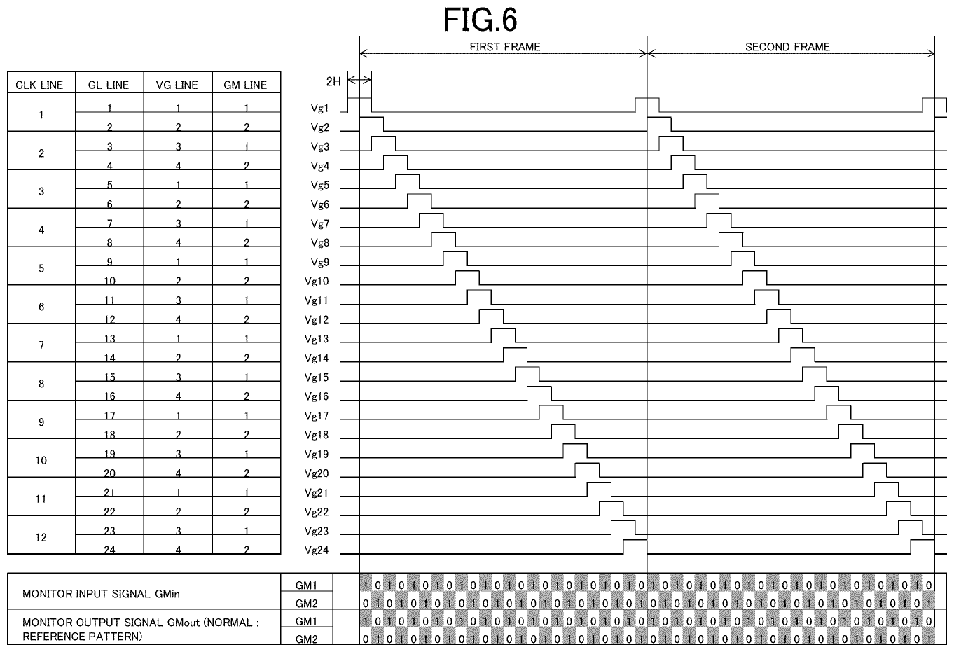

FIG. 6 is a timing chart during the normal operation in liquid crystal display device 100 of Example 1. FIG. 6 illustrates changes in voltages (gate voltages) Vgl to Vg24 of gate lines GL1 to GL24 in two consecutive frames. A high-level (gate-on voltage Vgh) period of gate voltage Vg is set to two horizontal scanning periods (2H), and gate-on voltage Vgh is sequentially input to each gate line 12 at intervals of 1H. “0” of monitor input signal GMin and monitor output signal GMout in FIG. 6 indicates that the voltage is a low level, and “1” indicates that the voltage is a high level. Monitor input signal GMin is a signal in which the high level and the low level are switched every 1H. Low-level monitor input signal GMin is input to monitor input signal line GMI2 during the period (1H) in which high-level monitor input signal GMin is input to monitor input signal line GMI1, and high-level monitor input signal GMin is input to monitor input signal line GMI2 during the period (1H) in which low-level monitor input signal GMin input to monitor input signal line GMI1. Monitor output signal GMout becomes the voltage level of monitor input signal GMin in the period in which corresponding gate voltage Vg is at the high level, and monitor output signal GMout is maintained at the voltage level of the preceding 1H in the period in which corresponding gate voltage Vg is at the low level.

For example, in the first 1H of the first frame, when gate-on voltage Vgh is input from gate voltage supply line VG1 to gate line GL1, failure detection transistor 21 connected to gate line GL1 is put into the on state, monitor input signal GMin at the high level (“1”) is input to monitor input signal line GMI1, and monitor output signal GMout at the high level (“1”) is output from monitor output signal line GMO1. When gate-on voltage Vgh is input from gate voltage supply line VG2 to gate line GL2, failure detection transistor 21 connected to gate line GL2 is put into the on state, monitor input signal GMin at the low level (“0”) is input to monitor input signal line GMI2, and monitor output signal GMout at the low level (“0”) is output from monitor output signal line GMO2.

In the following 1H, failure detection transistor 21 connected to gate line GL2 is maintained in the on state, monitor input signal GMin at the high level (“1”) is input to monitor input signal line GMI2, and monitor output signal GMout at the high level (“1”) is output from monitor output signal line GMO2. When gate-on voltage Vgh is input from gate voltage supply line VG3 to gate line GL3, failure detection transistor 21 connected to gate line GL3 is put into the on state, monitor input signal GMin at the low level (“0”) is input to monitor input signal line GMI3, and monitor output signal GMout at the low level (“0”) is output from monitor output signal line GMO3. Hereafter, the identical operation is repeated. When liquid crystal display device 100 operates normally, the voltage level of monitor output signal GMout becomes the state in FIG. 6. The output pattern for one frame of this voltage level is stored in memory 44 as the reference pattern.

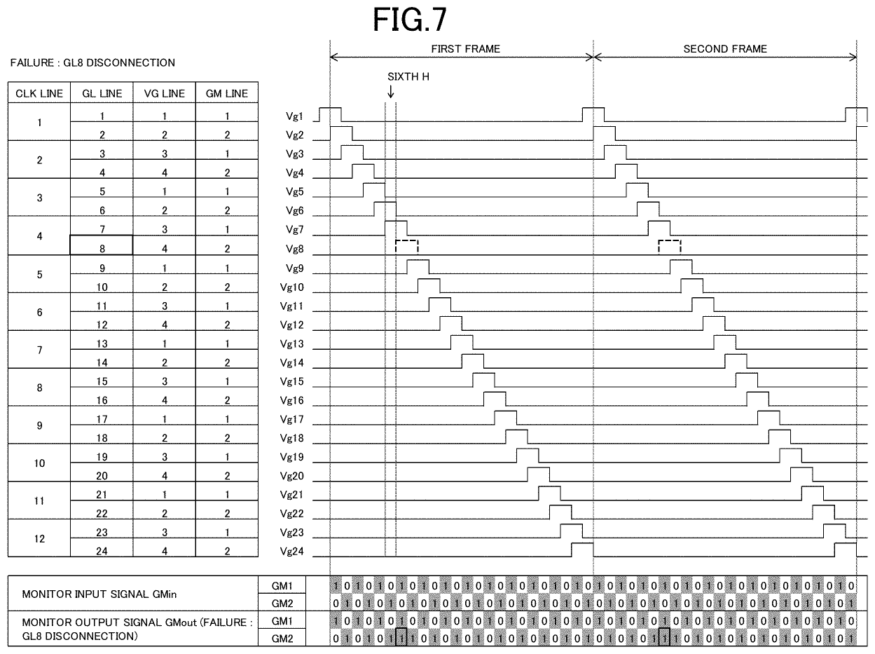

FIG. 7 is a timing chart during the failure in liquid crystal display device 100 of Example 1. FIG. 7 illustrates the state in which gate line GL8 is disconnected.

For example, in the sixth H, when gate-on voltage Vgh is input from gate voltage supply line VG2 to gate line GL6, failure detection transistor 21 connected to gate line GL6 is put into the on state, monitor input signal GMin at the high level (“1”) is input to monitor input signal line GMI2, and monitor output signal GMout at the high level (“1”) is output from monitor output signal line GMO2. When gate-on voltage Vgh is input from gate voltage supply line VG3 to gate line GL7, failure detection transistor 21 connected to gate line GL7 is put into the on state, monitor input signal GMin at the low level (“0”) is input to monitor input signal line GMI1, and monitor output signal GMout at the low level (“0”) is output from monitor output signal line GMO1.

In the following seventh H, failure detection transistor 21 connected to gate line GL7 is maintained in the on state, monitor input signal GMin at the high level (“1”) is input to monitor input signal line GMI1, and monitor output signal GMout at the high level (“1”) is output from monitor output signal line GMO1. In the identical seventh H, when gate-on voltage Vgh is input from gate voltage supply line VG4 to the gate line GL8, gate voltage Vg8 becomes the low level due to the disconnection failure of gate line GL8, and failure detection transistor 21 connected to gate line GL8 is not put into the on state, but maintained in the off state. When gate voltage Vg is at the low level, monitor output signal GMout holds the voltage level of the preceding 1H. Because the voltage level of monitor output signal GMout corresponding to gate line GL6 is held, monitor output signal GMout at the high level (“1”) is output from monitor output signal line GMO2.

In the following eighth H, because gate voltage Vg8 is still at the low level, monitor output signal GMout holds the voltage level of the preceding 1H, and monitor output signal GMout at the high level (“1”) is output from monitor output signal line GMO2. Hereafter, the same operation is repeated, and an output pattern for one frame is stored in memory 44.

Determination part 45 compares the output pattern (see FIG. 7) stored in memory 44 to the reference pattern (see FIG. 6) to detect the failure. In this case, determination part 45 determines the disconnection failure of gate line 12 because there is one point (“1”) in the output pattern that is different from the reference pattern. Because the different point appears on seventh H monitor output signal line GMO2, determination part 45 determines the disconnection failure of gate line GL8. Determination part 45 informs the outside of a determination result by a known method. Consequently, the presence or absence of the disconnection failure and the position of the disconnection failure of the gate line 12 can be detected.

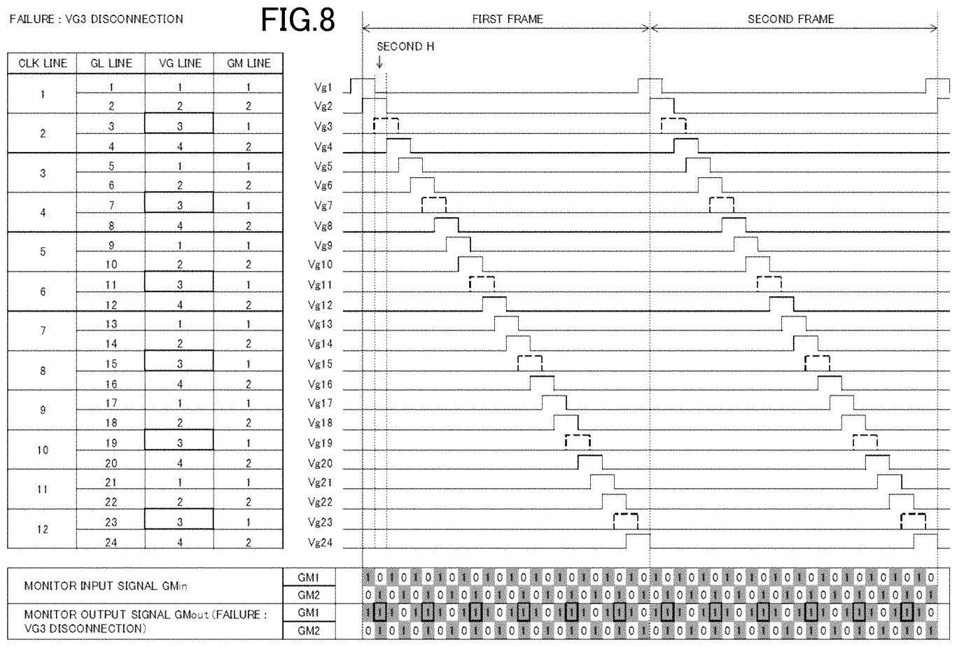

FIG. 8 is a timing chart during the failure in liquid crystal display device 100 of Example 1. FIG. 8 illustrates the state in which gate voltage supply line VG3 is disconnected.

For example, in the second H, when gate-on voltage Vgh is input from gate voltage supply line VG2 to gate line GL2, failure detection transistor 21 connected to gate line GL2 is put into the on state, monitor input signal GMin at the high level (“1”) is input to monitor input signal line GMI2, and monitor output signal GMout at the high level (“1”) is output from monitor output signal line GMO2. In the identical second H, gate voltage Vg3 becomes the low level due to the disconnection failure of gate voltage supply line VG3, and failure detection transistor 21 connected to gate line GL3 is not put into the on state, but maintained in the off state. In this case, because monitor output signal GMout holds the voltage level of the preceding 1H, monitor output signal GMout at the high level (“1”) is output from monitor output signal line GMO1. Hereafter, the identical operation is repeated, and the output pattern for one frame in FIG. 8 is stored in memory 44.

In this case, because a point different from the reference pattern in the output pattern appears in a period (4H period) for the number of gate voltage supply lines 31, determination part 45 determines the disconnection failure of gate voltage supply line 31. Because the different points appear on monitor output signal lines GMO1 of the second H, the sixth H, the tenth H, the fourteenth H, the eighteenth H, and the twenty-second H, determination part 45 determines the disconnection failure of gate voltage supply line VG3.

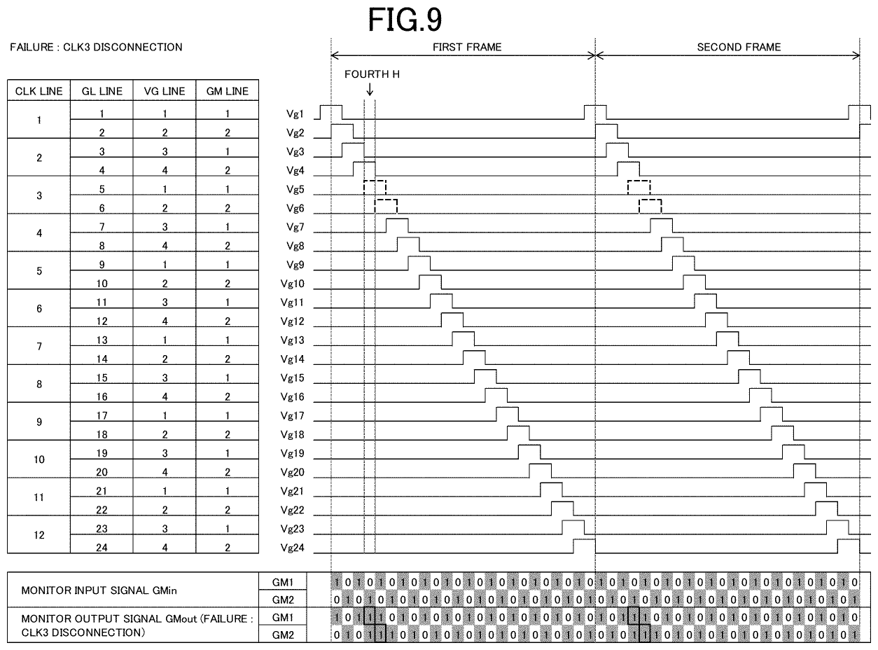

FIG. 9 is a timing chart during the failure in liquid crystal display device 100 of Example 1. FIG. 9 illustrates the state in which selection signal supply line CLK3 is disconnected.

For example, in the fourth H, when two selection transistors 21 connected to selection signal supply line CLK2 are put into the on state to input gate-on voltage Vgh from gate voltage supply line VG4 to gate line GL4, failure detection transistor 21 connected to gate line GL4 is put into the on state, monitor input signal GMin at the high level (“1”) is input to monitor input signal line GMI2, and monitor output signal GMout at the high level (“1”) is output from monitor output signal line GMO2. In the identical fourth H, gate voltage Vg5 becomes the low level due to the disconnection failure of selection signal supply line CLK3, and failure detection transistor 21 connected to gate line GL5 is not put into the on state, but maintained in the off state. In this case, because monitor output signal GMout holds the voltage level of the preceding 1H, monitor output signal GMout at the high level (“1”) is output from monitor output signal line GMO1.

In the following fifth H, because gate voltage Vg5 is still at the low level, monitor output signal GMout holds the voltage level of the preceding 1H, and monitor output signal GMout at the high level (“1”) is output from monitor output signal line GMO1. In the identical fifth H, gate voltage Vg6 also becomes the low level due to the disconnection failure of selection signal supply line CLK3, and failure detection transistor 21 connected to gate line GL6 is not put into the on state, but maintained in the off state. In this case, because monitor output signal GMout holds the voltage level of the preceding 1H, monitor output signal GMout at the high level (“1”) is output from monitor output signal line GMO2. In the following sixth H, because gate voltage Vg6 is still at the low level, monitor output signal GMout holds the voltage level of the preceding 1H, and monitor output signal GMout at the high level (“1”) is output from monitor output signal line GMO2. Hereafter, the identical operation is repeated, and the output pattern for one frame in FIG. 9 is stored in memory 44.

In this case, because the point different from the reference pattern in the output pattern appears continuously (2H) as the number (two) of gate lines 12 per block, determination part 45 determines the disconnection failure of selection signal supply line 32. Because the different point appears on monitor output signal lines GMO1, GMO2 of the fourth H and the fifth H, determination part 45 determines the disconnection failure of selection signal supply line CLK3.

In liquid crystal display device 100 of Example 1, the presence or absence of the disconnection failure and the position of the disconnection failure of gate line 12, gate voltage supply line 31, or selection signal supply line 32 can be detected based on the output pattern of monitor output signal GMout. For example, when only one point difference from the reference pattern appears in the output pattern, it can be determined that the disconnection failure is generated in any one of gate lines 12. When the points different from the reference pattern appear periodically at equal intervals in the output pattern, it can be determined that the disconnection failure is generated in any one of gate voltage supply lines 31. When the point different from the reference pattern appears continuously in the output pattern, it can be determined that the disconnection failure is generated in any one of selection signal supply lines 32. Each failure position can be detected based on the time the failure appears (horizontal scanning period).

### Example 2

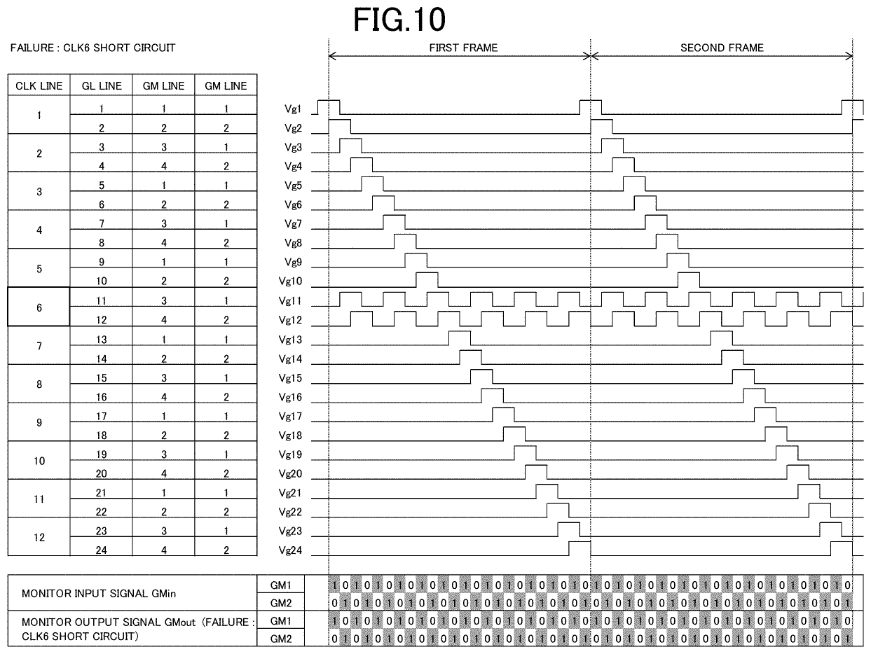

In liquid crystal display device 100 of Example 1, for example, when the short circuit failure is generated in selection signal supply line CLK6 to always put two selection transistors 21 connected to selection signal supply line CLK6 into the on state, there is a problem in that the short circuit failure cannot be detected. FIG. 10 is a timing chart when selection signal supply line CLK6 is short-circuited in liquid crystal display device 100 of Example 1.

When selection signal supply line CLK6 is short-circuited, because two selection transistors 21 connected to selection signal supply line CLK6 always becomes the on state, the voltage at gate voltage supply line VG3 is always applied to gate line GL11, and the voltage at gate voltage supply line VG4 is always input to gate line GL12. For this reason, gate voltage Vg11 in FIG. 10 is input to failure detection transistor 21 connected to gate line GL11, and gate voltage Vg12 in FIG. 10 is input to failure detection transistor 21 connected to gate line GL12. In this case, because the output pattern in FIG. 10 is identical to the reference pattern, determination part 45 determines that the failure point does not exist but the selection signal supply line is normal. As described above, the problem in that the presence or absence of the failure cannot be detected arises when selection signal supply line 32 is short-circuited.

For this reason, liquid crystal display device 100 of Example 2 further includes a configuration that can detect the presence or absence of the short circuit failure of selection signal supply line 32 in addition to the detection of the presence or absence of the disconnection failure and the position of the disconnection failure in gate line 12, gate voltage supply line 31, and selection signal supply line 32.

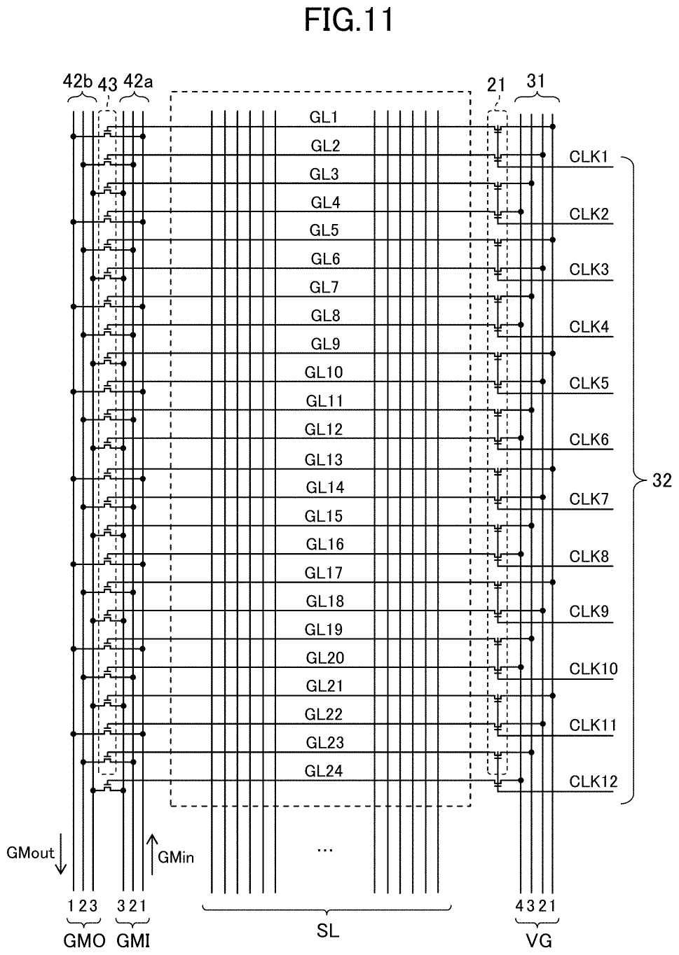

FIG. 11 is a plan view illustrating a configuration of liquid crystal display device 100 according to Example 2. In liquid crystal display device 100 of Example 2, 24 gate lines 12 (GL1 to GL24), 4 gate voltage supply lines 31 (VG1 to VG4), 12 selection signal supply lines 32 (CLK1 to CLK12), 3 monitor input signal lines 42a (GMI1, GMI2, GMI3), 3 monitor output signal lines 42b (GMO1, GMO2, GMO3), and two gate lines 12 per block are formed.

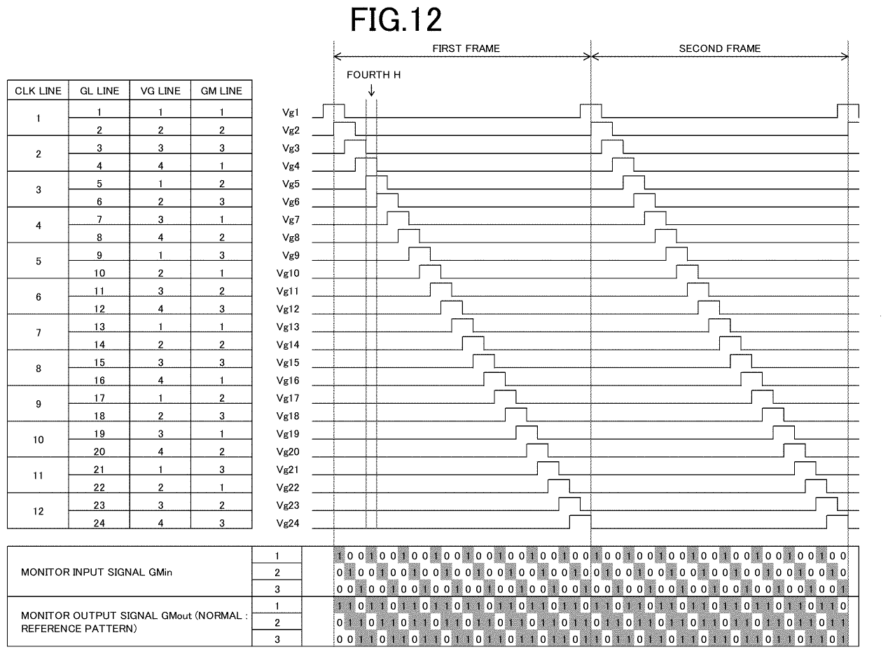

FIG. 12 is a timing chart during the normal operation in liquid crystal display device 100 of Example 2. In liquid crystal display device 100 of Example 2, monitor input signal GMin at high level (1H period) is repeatedly and sequentially input to monitor input signal lines GMI1, GMI2, GMI3. Monitor output signal GMout becomes the voltage level of monitor input signal GMin in the period in which corresponding gate voltage Vg is at the high level, and monitor output signal GMout is maintained at the voltage level of the preceding 1H in the period in which corresponding gate voltage Vg is at the low level.

For example, in the fourth H of the first frame, when gate-off voltage Vgl is input from gate voltage supply line VG3 to gate line GL3, failure detection transistor 21 connected to gate line GL3 is put into the off state, and monitor output signal GMout of monitor output signal line GMO3 holds the voltage level (“1”) of the preceding 1H and becomes the high level (“1”). When gate-on voltage Vgh is input from gate voltage supply line VG4 to gate line GL4, failure detection transistor 21 connected to gate line GL4 is put into the on state, monitor input signal GMin at the high level (“1”) is input to monitor input signal line GMI1, and monitor output signal GMout at the high level (“1”) is output from monitor output signal line GMO1. When gate-on voltage Vgh is input from gate voltage supply line VG1 to gate line GL5, failure detection transistor 21 connected to gate line GL5 is put into the on state, monitor input signal GMin at the low level (“0”) is input to monitor input signal line GMI2, and monitor output signal GMout at the low level (“0”) is output from monitor output signal line GMO2.

Hereafter, the identical operation is repeated. When liquid crystal display device 100 operates normally, monitor output signal GMout has the pattern in FIG. 12. The pattern is stored in memory 44 with the pattern for one frame as the reference pattern.

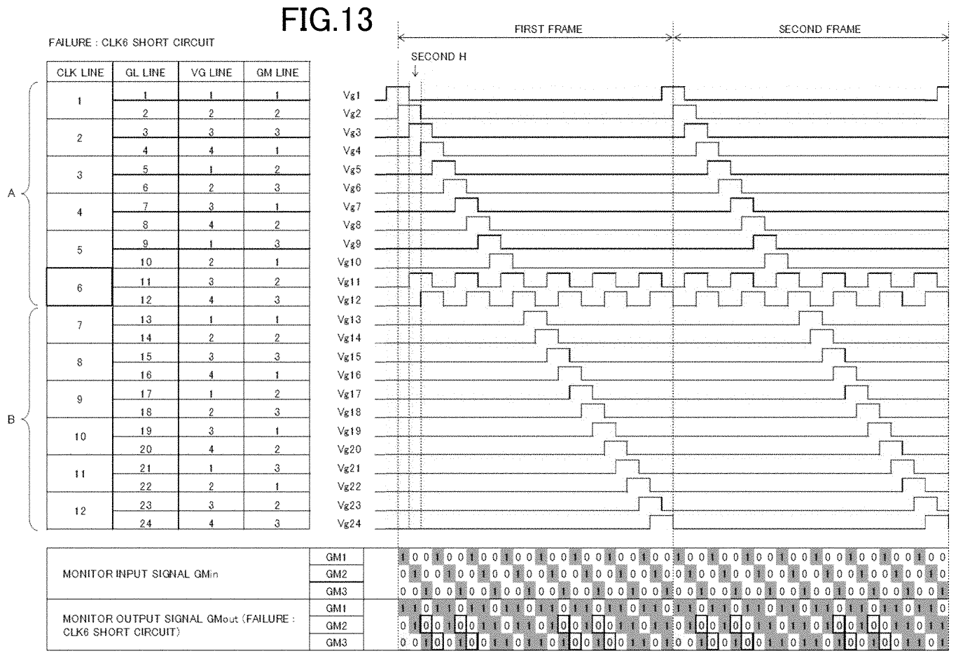

FIG. 13 is a timing chart when selection signal supply line 32 is short-circuited in liquid crystal display device 100 of Example 2. FIG. 13 illustrates the state in which selection signal supply line CLK6 is short-circuited.

For example, in the second H, when gate-off voltage Vgl is input from gate voltage supply line VG1 to gate line GL1, monitor output signal GMout of monitor output signal line GMO1 holds the voltage level (“1”) of the preceding 1H and becomes the high level (“1”). When gate-on voltage Vgh is input from gate voltage supply line VG2 to gate line GL2, failure detection transistor 21 connected to gate line GL2 is put into the on state, monitor input signal GMin at the high level (“1”) is input to monitor input signal line GMI2, and monitor output signal GMout at the high level (“1”) is output from monitor output signal line GMO2. When gate-on voltage Vgh is input from gate voltage supply line VG3 to gate line GL3, failure detection transistor 21 connected to gate line GL3 is put into the on state, monitor input signal GMin at the low level (“0”) is input to monitor input signal line GMI3, and monitor output signal GMout at the low level (“0”) is output from monitor output signal line GMO3. When gate-on voltage Vgh is input from gate voltage supply line VG3 to gate line GL11 due to the short circuit failure of selection signal supply line CLK6, failure detection transistor 21 connected to gate line GL11 is put into the on state, monitor input signal GMin at the high level (“1”) is input to monitor input signal line GMI2, and monitor output signal GMout at the high level (“1”) is output from monitor output signal line GMO2.

In the following third H, when gate-on voltage Vgh is input from gate voltage supply line VG3 to gate line GL3, failure detection transistor 21 connected to gate line GL3 is put into the on state, monitor input signal GMin at the high level (“1”) is input to monitor input signal line GMI3, and monitor output signal GMout at the high level (“1”) is output from monitor output signal line GMO3. When gate-on voltage Vgh is input from gate voltage supply line VG4 to gate line GL4, failure detection transistor 21 connected to gate line GL4 is put into the on state, monitor input signal GMin at the low level (“0”) is input to monitor input signal line GMI1, and monitor output signal GMout at the low level (“0”) is output from monitor output signal line GMO1.

When gate-on voltage Vgh is input from gate voltage supply line VG3 to gate line GL11 due to the short circuit failure of selection signal supply line CLK6, failure detection transistor 21 connected to gate line GL11 is put into the on state, monitor input signal GMin at the low level (“0”) is input to monitor input signal line GMI2, and monitor output signal GMout at the low level (“0”) is output from monitor output signal line GMO2. When gate-on voltage Vgh is input from gate voltage supply line VG4 to gate line GL12, failure detection transistor 21 connected to gate line GL12 is put into the on state, monitor input signal GMin at the high level (“1”) is input to monitor input signal line GMI3, and monitor output signal GMout at the high level (“1”) is output from monitor output signal line GMO3.

In the following fourth H, when gate-on voltage Vgh is input from gate voltage supply line VG4 to gate line GL4, failure detection transistor 21 connected to gate line GL4 is put into the on state, monitor input signal GMin at the high level (“1”) is input to monitor input signal line GMI1, and monitor output signal GMout at the high level (“1”) is output from monitor output signal line GMO1. When gate-on voltage Vgh is input from gate voltage supply line VG1 to gate line GL5, failure detection transistor 21 connected to gate line GL5 is put into the on state, monitor input signal GMin at the low level (“0”) is input to monitor input signal line GMI2, and monitor output signal GMout at the low level (“0”) is output from monitor output signal line GMO2.

When gate-on voltage Vgh is input from gate voltage supply line VG4 to gate line GL12 due to the short circuit failure of selection signal supply line CLK6, failure detection transistor 21 connected to gate line GL12 is put into the on state, monitor input signal GMin at the low level (“0”) is input to monitor input signal line GMI3, and monitor output signal GMout at the low level (“0”) is output from monitor output signal line GMO3.

Hereafter, the identical operation is repeated, and the output pattern for one frame in FIG. 13 is stored in memory 44. In this case, because the point different from the reference pattern in the output pattern appears continuously (2H) and periodically as the number (two) of gate lines 12 per block, determination part 45 determines the short circuit failure of selection signal supply line 32.

In liquid crystal display device 100 of Example 2, the presence or absence of the short circuit failure of selection signal supply line 32 can be detected based on the output pattern of monitor output signal GMout.

In order to detect the presence or absence of the short circuit failure of selection signal supply line 32, it is necessary to satisfy a condition (hereinafter, referred to as condition 1) that “the number of gate voltage supply lines 31 is not an integral multiple of the number of monitor output signal lines 42b (or monitor input signal lines 42a)”. In Example 2, the number (=4) of gate voltage supply lines 31 is not the integer multiple of the number (=3) of monitor output signal lines 42b (or monitor input signal lines 42a), but condition 1 is satisfied. Liquid crystal display device 100 of Example 2 is not limited to the configuration in FIG. 11 as long as the configuration satisfies condition 1.

### Example 31

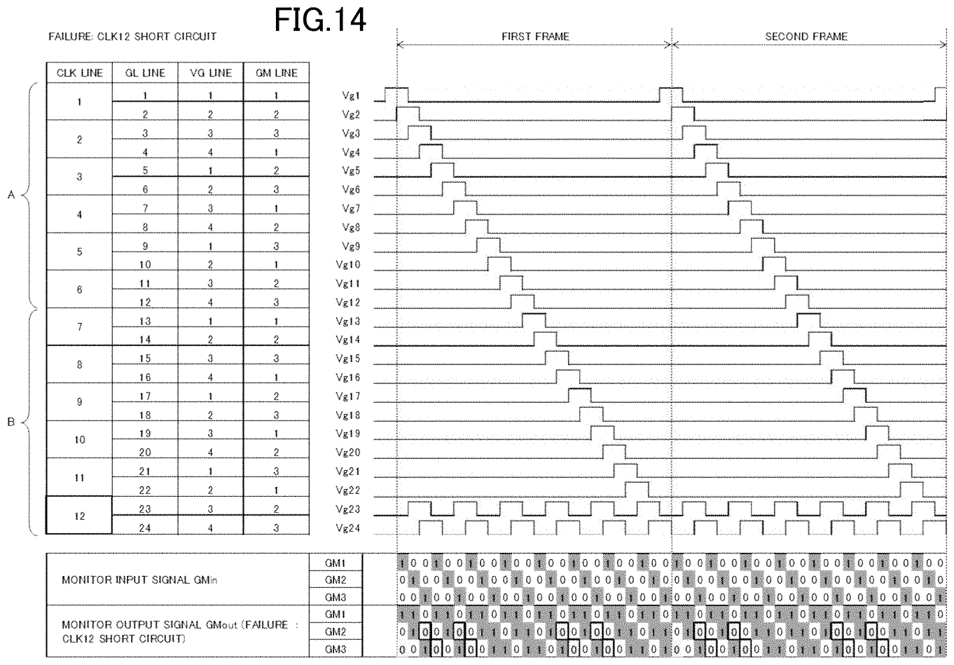

In liquid crystal display device 100 of Example 2, for example, the case that selection signal supply line CLK6 is short-circuited (see FIG. 13) and the case that selection signal supply line CLK12 is short-circuited (see FIG. 14) are identical to each other with respect to the output pattern of monitor output signal GMout, which results in a problem in that whether selection signal supply lines CLK6 fails or CLK12 fails cannot be detected. That is, the problem in that the position of the short circuit failure of selection signal supply line 32 cannot be detected arises.

For this reason, liquid crystal display device 100 of Example 3 further includes a configuration that can detect the presence or absence of the short circuit failure and the position of the short circuit failure of selection signal supply line 32 in addition to the detection of the presence or absence of the disconnection failure and the position of the disconnection failure in gate line 12, gate voltage supply line 31, and selection signal supply line 32.

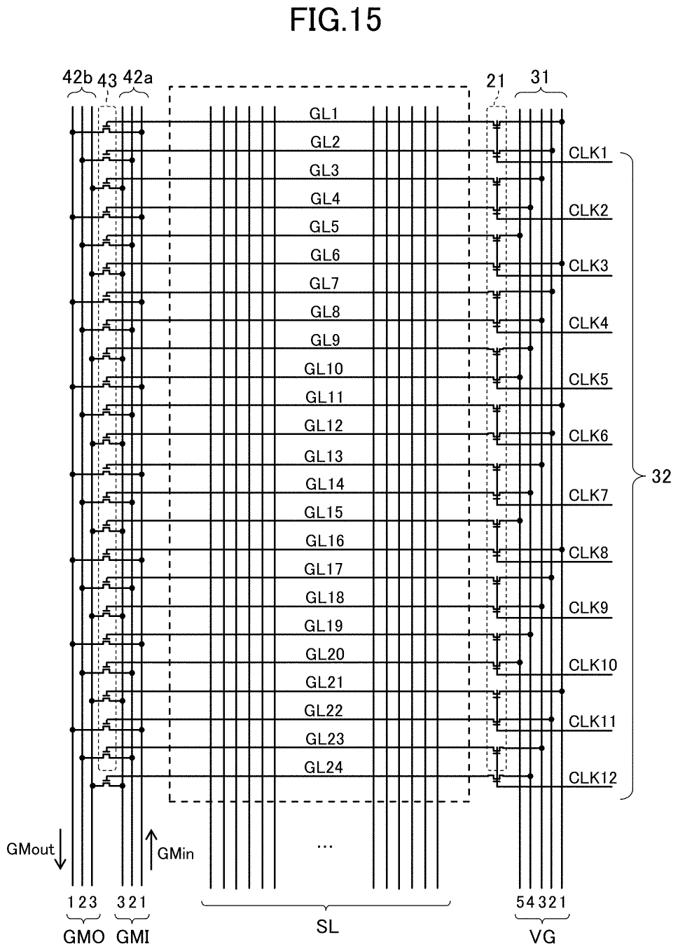

FIG. 15 is a plan view illustrating a configuration of liquid crystal display device 100 according to Example 3. In liquid crystal display device 100 of Example 3, 24 gate lines 12 (GL1 to GL24), 5 gate voltage supply lines 31 (VG1 to VG5), 12 selection signal supply lines 32 (CLK1 to CLK12), 3 monitor input signal lines 42a (GMI1, GMI2, GMI3), 3 monitor output signal lines 42b (GMO1, GMO2, GMO3), and two gate lines 12 per block are formed.

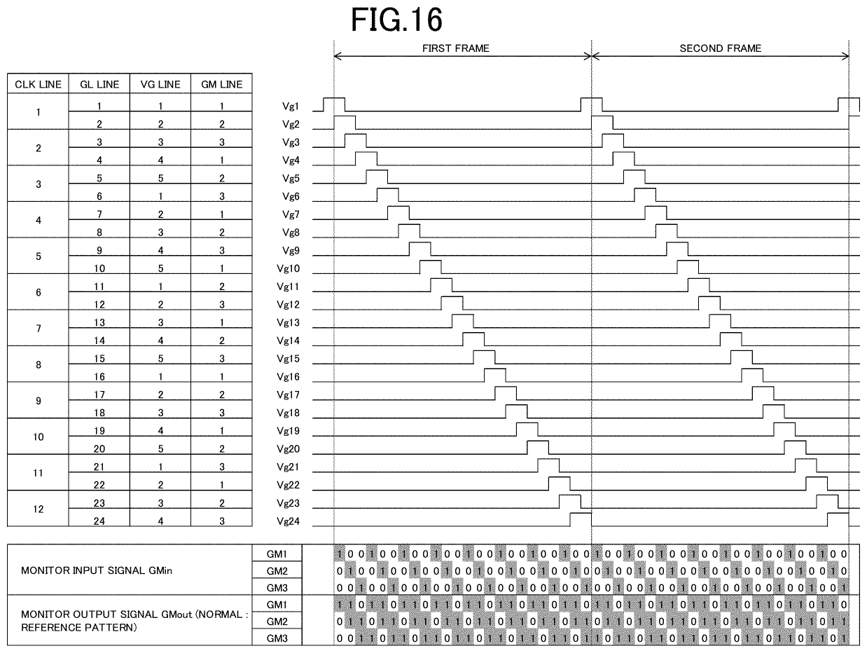

FIG. 16 is a timing chart during the normal operation in liquid crystal display device 100 of Example 3. In the liquid crystal display device 100 according to the third embodiment, similarly to the liquid crystal display device 100 according to the second embodiment, the monitor input signal GMin at high level is repeatedly and sequentially input to the monitor input signal lines GMI1, GMI2, and GMI3. Monitor output signal GMout becomes the voltage level of monitor input signal GMin in the period in which corresponding gate voltage Vg is at the high level, and monitor output signal GMout is maintained at the voltage level of the preceding 1H in the period in which corresponding gate voltage Vg is at the low level. When liquid crystal display device 100 operates normally, monitor output signal GMout has the pattern in FIG. 16, and the pattern is stored in memory 44 with the pattern for one frame as the reference pattern.

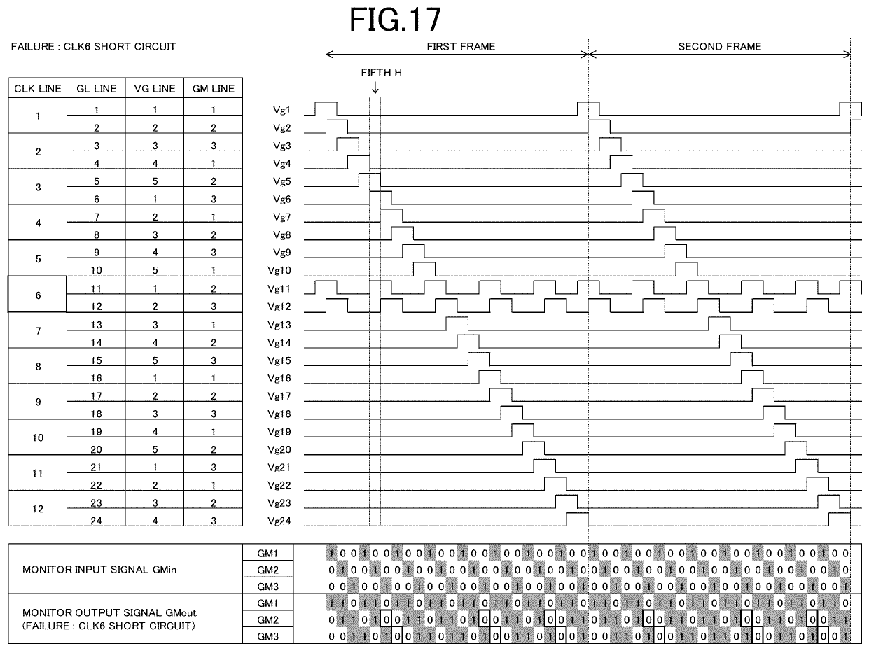

FIG. 17 is a timing chart when the selection signal supply line CLK6 is short-circuited in liquid crystal display device 100 of Example 3. When selection signal supply line CLK6 is short-circuited to always put selection transistors 21 connected to selection signal supply line CLK6 into the on state, because the gate voltages supplied to gate voltage supply lines VG1, VG2 are input to gate lines GL11, GL12, voltages Vg11, Vg12 at gate lines GL11, GL12 have waveforms in FIG. 17.

For example, in the fifth H, when gate-off voltage Vgl is input from gate voltage supply line VG4 to gate line GL4, monitor output signal GMout of monitor output signal line GMO1 holds the voltage level (“1”) of the preceding 1H and becomes the high level (“1”). When gate-on voltage Vgh is input from gate voltage supply line VG5 to gate line GL5, failure detection transistor 21 connected to gate line GL5 is put into the on state, monitor input signal GMin at the high level (“1”) is input to monitor input signal line GMI2, and monitor output signal GMout at the high level (“1”) is output from monitor output signal line GMO2. When gate-on voltage Vgh is input from gate voltage supply line VG1 to gate line GL6, failure detection transistor 21 connected to gate line GL6 is put into the on state, monitor input signal GMin at the low level (“0”) is input to monitor input signal line GMI3, and monitor output signal GMout at the low level (“0”) is output from monitor output signal line GMO3. When gate-on voltage Vgh is input from gate voltage supply line VG1 to gate line GL11 due to the short circuit failure of selection signal supply line CLK6, failure detection transistor 21 connected to gate line GL11 is put into the on state, monitor input signal GMin at the high level (“1”) is input to monitor input signal line GMI2, and monitor output signal GMout at the high level (“1”) is output from monitor output signal line GMO2.

In the following sixth H, when gate-on voltage Vgh is input from gate voltage supply line VG1 to gate line GL6, failure detection transistor 21 connected to gate line GL6 is put into the on state, monitor input signal GMin at the high level (“1”) is input to monitor input signal line GMI3, and monitor output signal GMout at the high level (“1”) is output from monitor output signal line GMO3. When gate-on voltage Vgh is input from gate voltage supply line VG2 to gate line GL7, failure detection transistor 21 connected to gate line GL7 is put into the on state, monitor input signal GMin at the low level (“0”) is input to monitor input signal line GMI1, and monitor output signal GMout at the low level (“0”) is output from monitor output signal line GMO1. When gate-on voltage Vgh is input from gate voltage supply line VG1 to gate line GL11 due to the short circuit failure of selection signal supply line CLK6, failure detection transistor 21 connected to gate line GL11 is put into the on state, monitor input signal GMin at the low level (“0”) is input to monitor input signal line GMI2, and monitor output signal GMout at the low level (“0”) is output from monitor output signal line GMO2. When gate-on voltage Vgh is input from gate voltage supply line VG2 to gate line GL12 due to the short circuit failure of selection signal supply line CLK6, failure detection transistor 21 connected to gate line GL12 is put into the on state, monitor input signal GMin at the high level (“1”) is input to monitor input signal line GMI3, and monitor output signal GMout at the high level (“1”) is output from monitor output signal line GMO3.

Hereafter, the identical operation is repeated, and the output pattern for one frame in FIG. 17 is stored in memory 44. In this case, because the point different from the reference pattern in the output pattern appears continuously (2H) and periodically as the number (two) of gate lines 12 per block, determination part 45 determines the short circuit failure of selection signal supply line 32. Because the different point appears on the sixth H and the seventh H, the fifteenth H and the sixteenth H, and the twenty-first H and the twenty-second H, determination part 45 determines the failure of selection signal supply line CLK6.

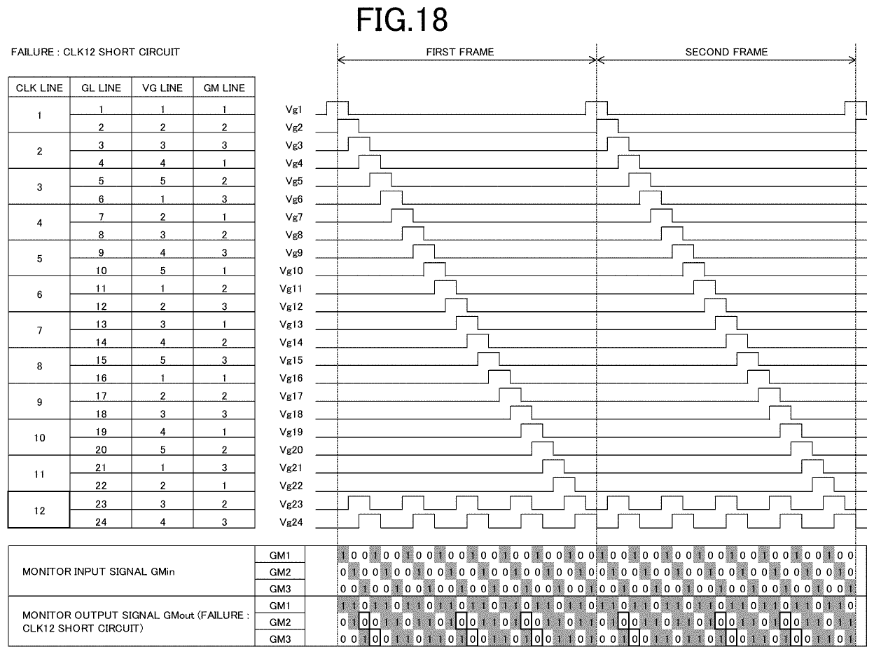

FIG. 18 is a timing chart when the selection signal supply line CLK12 is short-circuited in liquid crystal display device 100 of Example 3. When selection signal supply line CLK12 is short-circuited to always put selection transistors 21 connected to selection signal supply line CLK12 into the on state, because the gate voltages supplied to gate voltage supply lines VG3, VG4 are input to gate lines GL23, GL24, voltages Vg23, Vg24 at gate lines GL23, GL24 have waveforms in FIG. 18.

When the same operation as the operation in FIG. 17 is performed, the output pattern in FIG. 18 is obtained, and stored in memory 44. In this case, because the point different from the reference pattern in the output pattern appears continuously (2H) and periodically as the number (two) of gate lines 12 per block, determination part 45 determines the short circuit failure of selection signal supply line 32. Because the different point appears on the third H and the fourth H, the twelfth H and the thirteenth H, and the eighteenth H and the nineteenth H, determination part 45 determines the failure of selection signal supply line CLK12.

As described above, when the output pattern (see FIG. 17) in the case that selection signal supply line CLK6 is short-circuited and the output pattern (see FIG. 18) in the case that selection signal supply line CLK12 is short-circuited are compared to each other, the timing of the appearance of the point different from the reference pattern varies, so that determination part 45 can detect which selection signal supply line 32 fails, namely, the position of the short circuit failure of selection signal supply line 32 based on the time (horizontal scanning period) the failure appears.

At this point, in the configuration (Example 2) of FIG. 11, the output pattern becomes identical when correspondence between number of gate voltage supply line 31 and number of monitor input signal line 42a (monitor output signal line 42b) has periodicity. For example, in FIGS. 13 and 14, the correspondence between an A block and a B block becomes identical. In this case, the output patterns during the disconnection failure of selection signal supply lines CLK1, CLK7 become identical, the output patterns during the disconnection failure of selection signal supply line CLK2, CLK8 become identical, the output patterns during the disconnection failure of selection signal supply line CLK3, CLK9 become identical, the output patterns during the disconnection failure of selection signal supply lines CLK4, CLK10 become identical, and the output patterns during the disconnection failure of selection signal supply lines CLK5, CLK11 become identical, and the output patterns during the disconnection failure of selection signal supply lines CLK6, CLK12 become identical. For this reason, the position of the short circuit failure of selection signal supply line 32 cannot correctly be detected.

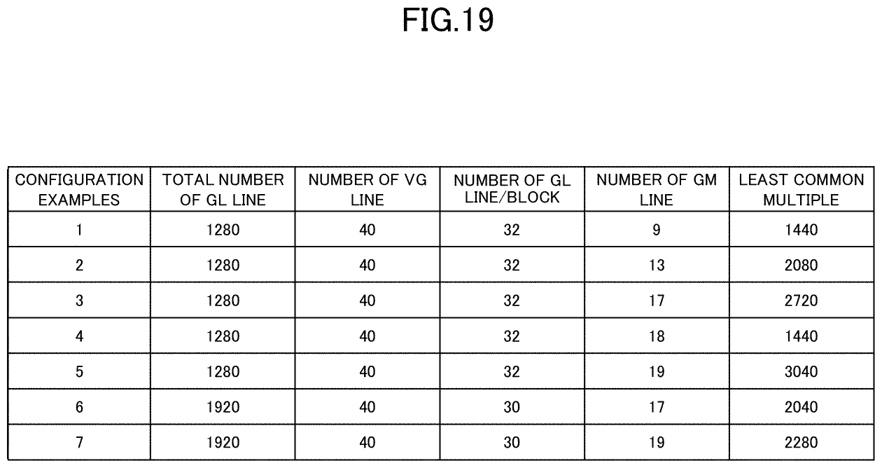

In order to detect the position of the short circuit failure of selection signal supply line 32, it is necessary to satisfy condition 1 and a condition (hereinafter, referred to as condition 2) that “a least common multiple of the number of gate voltage supply lines 31, the number of gate lines 12 included in one block, and the number of monitor output signal lines 42b (or the number of monitor input signal lines 42a) is greater than or equal to the total number of gate lines 12”. In Example 3, the number (=5) of gate voltage supply lines 31 is not the integer multiple of the number (=3) of monitor output signal lines 42b (or the monitor input signal lines 42a), but satisfies condition 1, and the least common multiple (=30) of the number (=5) of gate voltage supply lines 31, the number (=2) of gate lines 12 included in one block, and the number (=3) of monitor output signal lines 42b is greater than or equal to the total number (=24) of gate lines 12 to satisfy condition 2. Liquid crystal display device 100 of Example 3 is not limited to the configuration in FIG. 15 as long as conditions 1, 2 are satisfied. Specifically, for example, configuration examples 1 to 7 in FIG. 19 can be applied to liquid crystal display device 100 of Example 3.

The number of gate voltage supply lines 31 and the number of monitor output signal lines 42b (or monitor input signal lines 42a) may be set to a combination in which widths of the left and right (row direction) frame regions 10b of display region 10a are substantially equal to each other among the combinations satisfying conditions 1, 2.

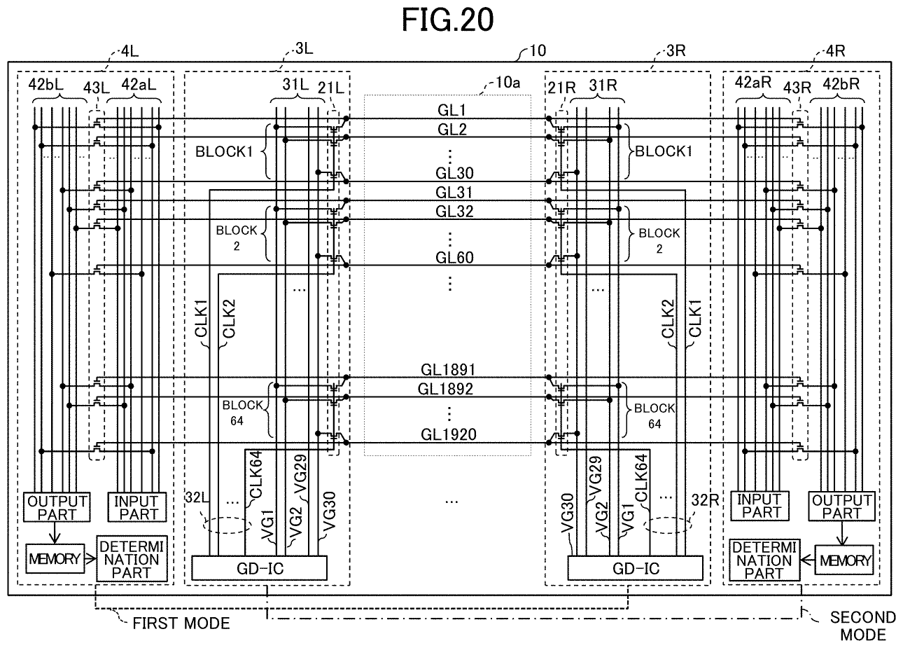

In the display device of the present invention, gate selectors 3 may be disposed on the left and right of display region 10a, and failure detector 4 may be disposed on the left and right of display region 10a. Specifically, as illustrated in FIG. 20, liquid crystal display device 100 may include gate selector 3R and failure detector 4R that are disposed on the right side of display region 10a and gate selector 3L and failure detector 4L that are disposed on the left side of display region 10a. Gate selector 3R includes selection transistor 21R, gate voltage supply line 31R, and selection signal supply line 32R, and gate selector 3L includes selection transistor 21L, gate voltage supply line 31L, and selection signal supply line 32L. Failure detector 4R includes failure detection transistor 43R, monitor input signal line 42aR, monitor output signal line 42bR, an input part, an output part, a memory, and a determination part, and failure detector 4L includes failure detection transistor 43L, monitor input signal line 42aL, monitor output signal line 42bL, an input part, an output part, a memory, and a determination part. With the above configuration, for example, gate selector 3R drives gate line 12 while failure detector 4L detects the failure in gate line 12, gate voltage supply line 31R, and selection signal supply line 32R in a first mode, and gate selector 3L drives gate line 12 while failure detector 4R detects the failure in gate line 12, gate voltage supply line 31L, and selection signal supply line 32L in a second mode. Liquid crystal display device 100 switches between the first mode and the second mode in a predetermined period (for example, every plurality of frames). Consequently, for example, a fluctuation in a threshold voltage (Vth) of selection transistor 21 that is generated when only one of the gate selectors (for example, gate selector unit 3R) is driven can be prevented, so that degradation of display quality can be prevented. For example, liquid crystal display device 100, when the failure is generated in at least one of gate voltage supply line 31R and selection signal supply line 32R in the first mode, performs the subsequent operation in the second mode, and when the failure is generated in at least one of gate voltage supply line 31L and selection signal supply line 32L in the second mode, performs the subsequent operation in the first mode. Consequently, even if the failure is generated in gate voltage supply line 31 or selection signal supply line 32, the image display and the operation of the failure detection can be maintained.

In the above, the specific embodiments of the present application have been described, but the present application is not limited to the above-mentioned embodiments, and various modifications may be made as appropriate without departing from the spirit of the present application.

1. A display device comprising:
a plurality of source lines extending in a first direction;
a plurality of gate lines extending in a second direction;
a plurality of selection transistors in each of which a first conduction electrode is electrically connected to each of the plurality of gate lines;
a plurality of selection signal supply lines each electrically connected to a control electrode of each of the plurality of selection transistors, each of the selection signal supply lines being electrically connected to the control electrode of at least two of the selection transistors;
a plurality of gate voltage supply lines each connected to a second conduction electrode of each of the plurality of selection transistors, each of the gate voltage supply lines being connected to the second conduction electrode of at least two of the selection transistors;
a gate driver electrically connected to the plurality of selection signal supply lines and the plurality of gate voltage supply lines;
a plurality of failure detection transistors in each of which a control electrode is electrically connected to each of the plurality of gate lines;
a plurality of monitor input signal lines each electrically connected to a first conduction electrode of each of the plurality of failure detection transistors, each of the monitor input signal lines being electrically connected to the first conduction electrode of at least two of the failure detection transistors; and
a plurality of monitor output signal lines each electrically connected to a second conduction electrode of each of the plurality of failure detection transistors, each of the monitor output signal lines being electrically connected to the second conduction electrode of at least two of the failure detection transistors.

2. The display device according to claim 1, wherein each of the plurality of failure detection transistors electrically connected to one monitor input signal line included in the plurality of monitor input signal lines, among the plurality of failure detection transistors, is electrically connected to one monitor output signal line included in the plurality of monitor output signal lines.

3. The display device according to claim 1, further comprising a determination part that determines a failure of at least one of the plurality of gate lines, the plurality of gate voltage supply lines, and the plurality of selection signal supply lines based on a voltage level of a monitor output signal output from the plurality of monitor output signal lines.

4. The display device according to claim 3, wherein the determination part detects a position of the failure when the failure is generated in at least one of the plurality of gate lines, the plurality of gate voltage supply lines, and the plurality of selection signal supply lines.

5. The display device according to claim 3, wherein the determination part determines the failure based on a pattern for one frame of the voltage level of the monitor output signal.

6. The display device according to claim 1, wherein the number of the plurality of gate voltage supply lines is not an integral multiple of the number of the plurality of monitor output signal lines.

7. The display device according to claim 6, wherein a least common multiple of the number of the plurality of gate voltage supply lines, the number of the gate lines included in one block, and the number of the plurality of monitor output signal lines is greater than or equal to a total number of the plurality of gate lines.

8. A display device comprising:
a plurality of source lines extending in a first direction;
a plurality of gate lines extending in a second direction;
a plurality of first selection transistors in each of which a first conduction electrode is electrically connected to a first end of each of the plurality of gate lines;
a plurality of second selection transistors in each of which a first conduction electrode is electrically connected to a second end of each of the plurality of gate lines;
a plurality of first selection signal supply lines each electrically connected to a control electrode of each of the plurality of first selection transistors, each of the first selection signal supply lines being electrically connected to the control electrode of at least two of the first selection transistor;
a plurality of second selection signal supply lines each electrically connected to a control electrode of each of the plurality of second selection transistors, each of the second selection signal supply lines being electrically connected to the control electrode of at least two of the second selection transistor;
a plurality of first gate voltage supply lines each connected to a second conduction electrode of each of the plurality of first selection transistors, each of the first gate voltage supply lines being electrically connected to the second conduction electrode of at least two of the selection transistors;
a plurality of second gate voltage supply lines each connected to a second conduction electrode of each of the plurality of second selection transistors, each of the second gate voltage supply lines being electrically connected to the second conduction electrode of at least two of the selection transistors;
a first gate driver electrically connected to the plurality of first selection signal supply lines and the plurality of first gate voltage supply lines;
a second gate driver electrically connected to the plurality of second selection signal supply lines and the plurality of second gate voltage supply lines;
a plurality of first failure detection transistors in each of which a control electrode is electrically connected to the second end of each of the plurality of gate lines;
a plurality of second failure detection transistors in each of which a control electrode is electrically connected to the first end of each of the plurality of gate lines;
a plurality of first monitor input signal lines each electrically connected to a first conduction electrode of each of the plurality of first failure detection transistors, each of the first monitor input signal lines being electrically connected to the first conduction electrode of each of at least two of the first failure detection transistors;
a plurality of second monitor input signal lines each electrically connected to a first conduction electrode of each of the plurality of second failure detection transistors, each of the second monitor input signal lines being electrically connected to the first conduction electrode of each of at least two of the second failure detection transistors;
a plurality of first monitor output signal lines each electrically connected to a second conduction electrode of each of the plurality of first failure detection transistors, each of the first monitor output signal lines being electrically connected to the second conduction electrode of each of at least two of the first failure detection transistors; and
a plurality of second monitor output signal lines each electrically connected to a second conduction electrode of each of the plurality of second failure detection transistors, each of the second monitor output signal lines being electrically connected to the second conduction electrode of each of at least two of the second failure detection transistors.

9. The display device according to claim 8, wherein the display device includes:
a first mode in which the plurality of gate lines are driven by the plurality of first selection transistors, the plurality of first selection signal supply lines, the plurality of first gate voltage supply lines, and the first gate driver while a failure of at least one of the plurality of gate lines, the plurality of first gate voltage supply lines, and the plurality of first selection signal supply lines is determined based on a voltage level of a first monitor output signal output from the plurality of first monitor output signal lines, and
a second mode in which the plurality of gate lines are driven by the plurality of second selection transistors, the plurality of second selection signal supply lines, the plurality of second gate voltage supply lines, and the second gate driver while a failure of at least one of the plurality of gate lines, the plurality of second gate voltage supply lines, and the plurality of second selection signal supply lines is determined based on a voltage level of a second monitor output signal output from the plurality of second monitor output signal lines.

10. The display device according to claim 9, wherein the first mode and the second mode are mutually switched in a predetermined period.

11. The display device according to claim 9, wherein when the failure is generated in at least one of the plurality of first gate voltage supply lines and the plurality of first selection signal supply lines in the first mode, subsequent operation is performed in the second mode, and
when the failure is generated in at least one of the plurality of second gate voltage supply lines and the plurality of second selection signal supply lines in the second mode, subsequent operation is performed in the first mode.

12. The display device according to claim 10, wherein when the failure is generated in at least one of the plurality of first gate voltage supply lines and the plurality of first selection signal supply lines in the first mode, subsequent operation is performed in the second mode, and
when the failure is generated in at least one of the plurality of second gate voltage supply lines and the plurality of second selection signal supply lines in the second mode, subsequent operation is performed in the first mode.
